(19) United States
(12) Patent Application Publication
(10) Pub. No.: US 2016/0249472 A1
(43) Pub. Date: Aug. 25, 2016

(54) PROTECTIVE COVER FOR MOBILE DEVICE HAVING STAND EXTENDING FROM INTERNAL SURFACE

(71) Applicant: Incipio Technologies, Inc., Irvine, CA (US)

(72) Inventor: Peter Tu, Long Beach, CA (US)

(73) Assignee: Incipio Technologies, Inc., Irvine, CA (US)

(21) Appl. No.: 15/049,009

(22) Filed: Feb. 20, 2016

Related U.S. Application Data
(60) Provisional application No. 62/129,756, filed on Mar. 6, 2015.
(60) Provisional application No. 62/119,079, filed on Feb. 20, 2015.

(51) Int. Cl. H05K 5/02; F16M 13/00; H05K 5/03; A45C 11/00

(52) U.S. Cl. CPC H05K 5/0234; A45C 11/00; F16M 13/005; H05K 5/0204; H05K 5/03; A45C 2011/001; A45C 2011/002; A45C 2011/003; A45C 2200/15

(57) ABSTRACT

A protective case for a mobile device having a shell portion to retentively house the mobile device, a cover portion that can cover a mobile device retentively housed in the shell portion, and a flexible panel portion connecting the shell portion to the cover portion. The cover portion can be adjusted from in front of the shell portion to behind the shell portion by flexing the flexible panel. A pivot stand is attached to the inner surface of the cover portion at a hinge. The pivot stand is configured to pivot outwardly along said hinge to support the case in an operating position.

### INCORPORATION BY REFERENCE TO RELATED APPLICATIONS

This application claims the benefit of priority to U.S. Provisional Application Nos. 62/119,079, filed Feb. 20, 2015 and 62/129,756, filed Mar. 6, 2015. All of the above applications are hereby incorporated herein by reference in their entirety and are to be considered a part of this specification.

### BACKGROUND OF THE INVENTION

1. Field of the Invention

This patent document relates to user removable protective enclosures or cases for mobile devices and more particularly to such cases that have a pivot stand for supporting the case and mobile device to stand on edge. Description of the Related Art

Mobile consumer electronic products, such as smart and cellular phones, computing tablets, MP3/audio/video players, gaming devices and laptops are continuously and rapidly evolving to meet expanding consumer demands. Such devices are becoming more and more powerful, connected, and interactive, and employ bigger and bigger screens. For example, the most recent generation of iPhone® 6 Plus introduced in September 2014 provides nearly double the screen space of the original iPhone (1st generation) introduced in 2007. (iPhone is a trademark of Apple Inc.) At the same time, users are looking to improve ways to protect, conveniently and elegantly transport, and use such devices to maximize utility and user experience.

Some protective cases for mobile devices, such as the Incipio Kickstand® and Kicksnap® branded cases are equipped with an extendable stand on the outer surface of the backside of the case. (Incipio, Kickstand, and Kicksnap are registered trademarks of Incipio, LLC.) However, such a design is not functional in wallet or folio type cases that have both a back cover that protects the backside of the device and a front cover that covers and protects the screen when the case is closed. This is because, in operation, the front cover when opened would tend to interfere with a stand extending from the outer surface of the back cover. Additionally, the inclusion of such a stand on the outer surface of a wallet type cover can detract from the aesthetic appeal that customers are seeking from such wallet-type cases.

The inventors here have recognized that there is a need for a wallet-type protective case for mobile electronic devices that includes an extendable stand that is capable of standing the case and mobile device on edge so as to provide multiple viewing/operating positions yet is concealed from view when the case is in the closed position.

### SUMMARY OF THE INVENTION

Disclosed are numerous aspects of a unique and inventive protective case configured to receive, retain and protect a mobile device that includes a front face and a back face that define the height of the mobile device, a perimeter defined by top-end, bottom-end, right, and left sides residing between the front and back faces, and corners defined at the intersecting regions of the sides. The case may be for a mobile device that is in the form of a tablet, a mobile phone, an MP3 audio player, a gaming device, or other portable handheld electronic device and may have one or more touchscreens, including on its front face and/or back face.

The protective case is, in a first aspect, generally comprised of three primary components: (1) a back cover shell portion configured to reversibly receive and retain the mobile device, (2) a flexible hinge panel portion; and (3) a front cover portion that includes a hinged stand that extends from the inner surface thereof. The shell portion includes a compartment that is defined by wall structures having an inner and outer surfaces. The compartment is dimensioned to generally correspond with the sides and back face of the mobile device for which it is configured to house. The shell portion is configured so that the user may access various user interfaces of the mobile device (e.g., touch screen, home button, power and volume buttons, speaker and charging connections, etc.) yet also retain the mobile device within the shell compartment. The cover portion is generally configured to cover the front face of the mobile device and is attached to the shell portion via the flexible hinge panel portion. The hinge panel portion may be attached to any portion or surface of the shell portion including but not limited to the outer or inner surfaces, the mid region, or along or near a side thereof as illustrated in the drawings herein.

The shell portion may be made of any suitable material. In one aspect the shell is manufactured of a flexible polymer such as polycarbonate and/or fiber (e.g., carbon or Kevlar) reinforced plastic. The shell may be more rigid, less rigid, or have generally the same rigidity as the front cover portion. The hinge panel portion may be formed of a flexible material so that the front cover portion can be moved or rotated from a closed position wherein it overlies the front face of the mobile device to a completely open position wherein the outer surface of the front cover is adjacent and/or in contact with the outer surface of the shell portion. It is also contemplated that the hinge panel may be formed of a mechanical hinge, like those used in a conventional door mount, but with one side connected to the shell portion and the other side formed within or connected to the front cover.

The hinged stand that extends from the inner surface of the front cover is configured to be capable of opening to a defined position to support the case and mobile device to stand on edge at one or more angles or viewing/operation positions. A strap or other means may be used to restrain or limit the extendibility of the hinged stand to stabilize the stand or define extendable position of the stand. The hinged stand may be co-molded with or as part of the front cover and may be dimensioned to extend any distance within the dimensions of the front cover. For example the hinged stand may extend only a small area less than a third the length of the front cover, may extend the full or nearly the full length of the front cover, or may extend around half the length of the front cover. In one construction, the cover is constructed of outer surface or panel having a first material or construction and an inner surface or panel having a second material or construction. The hinged stand may be constructed of or as an extension of the inner panel. In another aspect, the hinged stand may be formed as a separate component that is formed of yet another material or construction different than that used in the outer or inner panel of the front cover and then attached (e.g., mechanically and/or adhesively) or otherwise incorporated into the front cover so as to be extendable from the inner surface of the front cover. The ornamental aspects of the shape and/or location of the hinged stand alone and/or in relation to the other ornamental features of the case and the overall case design as a whole is also within the scope of this application.

Each of the foregoing and various aspects, together with those set forth in the claims and summarized above or otherwise disclosed herein, including the drawings, may be combined to form claims for a device, apparatus, system, method of manufacture, and/or use without limitation.

### BRIEF DESCRIPTION OF THE DRAWINGS

These and other features, aspects and advantages are described below with reference to the drawings, which are intended to illustrate but not to limit the invention. In the drawings, like reference characters denote corresponding features consistently throughout similar embodiments.

FIG. 1 is a line drawing front perspective view of a protective case for a mobile device without the mobile device being received within the back cover shell portion of the case and the case being in the fully closed position with the front cover of the case closed over and completely covering the front of the shell portion. The illustrated case is configured for a Samsung Galaxy phone (not illustrated here, but illustrated in FIGS. 3, 6 and 8) that can be removably received and retained within the shell portion of the case.

FIGS. 2A-2F are front face, back face, left side, right side, top side and bottom side views of the protective case in the closed position illustrated in FIG. 1. The phone is not depicted as being housed in the case.

FIG. 2G is a cross-sectional view of the protective case illustrated in FIG. 2A taken along cross-section line 2G-2G showing in greater detail the construction of the case and the relationship and configuration of the shell, cover and panel portions and the attachment between the hinged panel and the shell portion.

FIG. 3 is a perspective view of the protective case illustrated in FIG. 1 in a first open position with a model of the mobile device received and retained therein.

FIG. 4 is a front perspective view drawing of the protective case illustrated in FIG. 1 in a second open position without a mobile device received within the case, wherein the front cover is adjacent to and nearly in contact in parallel alignment with the outer surface of the back of the shell portion.

FIGS. 5A-5F are front face, back face, left side, right side, top side and bottom side views of the protective case illustrated in FIG. 4 in the second open position.

FIG. 6 illustrates the protective case illustrated in FIG. 1 in an operating position with the mobile device received within the shell and the front cover of the case in an open position with the hinged stand extending from the internal surface of the front cover of the case in an open position to support the case, and hence the mobile device therein, along a longitudinally extending edge.

FIGS. 7A-7B are additional back face and front face perspective views, respectively, of the protective case illustrated in FIG. 6 with the mobile device removed from the case and further illustrating the various features and construction of the case, including the operation of the hinged stand.

FIG. 8 further illustrates the hinged stand and retention strap mechanism that limits the extendibility of the stand.

Each drawing is generally to scale and hence relative dimensions of the various layers can be determined from the drawings.

### DETAILED DESCRIPTION OF THE PREFERRED EMBODIMENT

As summarized above and illustrated in the drawings, disclosed herein are various aspects of a protective case for a mobile device capable of minimizing bulkiness and weight, yet maintaining a high level of protection. Many of those aspects are summarized above and illustrated in the drawings.

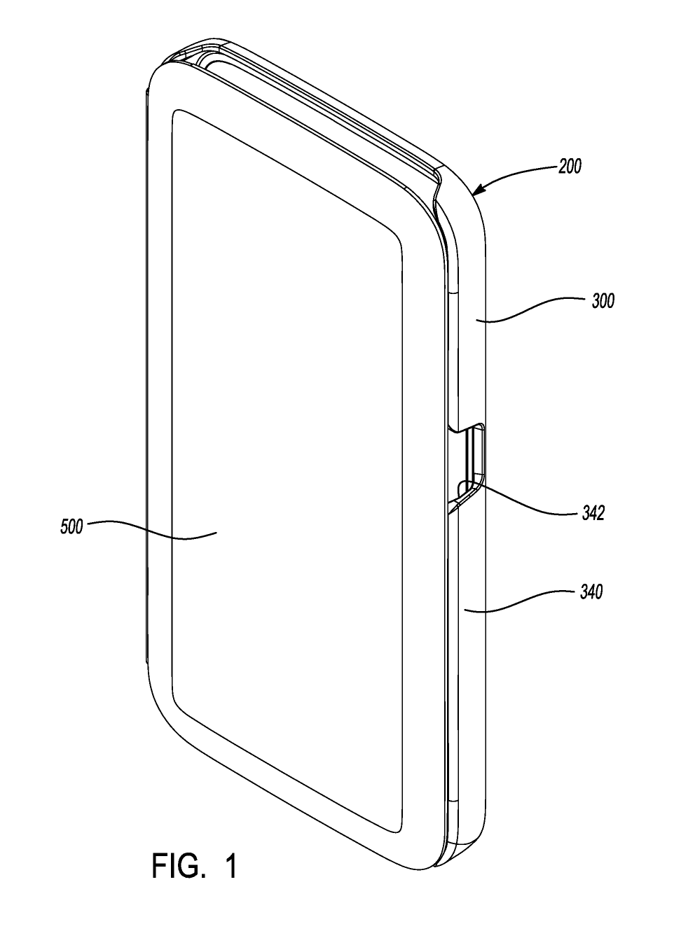

Commonly disclosed in FIGS. 1-8 is a protective enclosure or case 200 for a mobile device 100, which individually and collectively illustrate, by way of example only, various of the configuration, construction, and operational aspects of the case.

In this particular implementation, the case is configured for a Samsung Galaxy mobile or smartphone device. It should be understood, however, that the case may be configured for any mobile device or electronic device, including but not limited to portable or cellular phones, PDAs, MPS or audio/video devices, gaming devices, laptop computers or computing tablet devices made by Samsung, Apple, Microsoft, Dell, HTC, and numerous other manufacturers and suppliers.

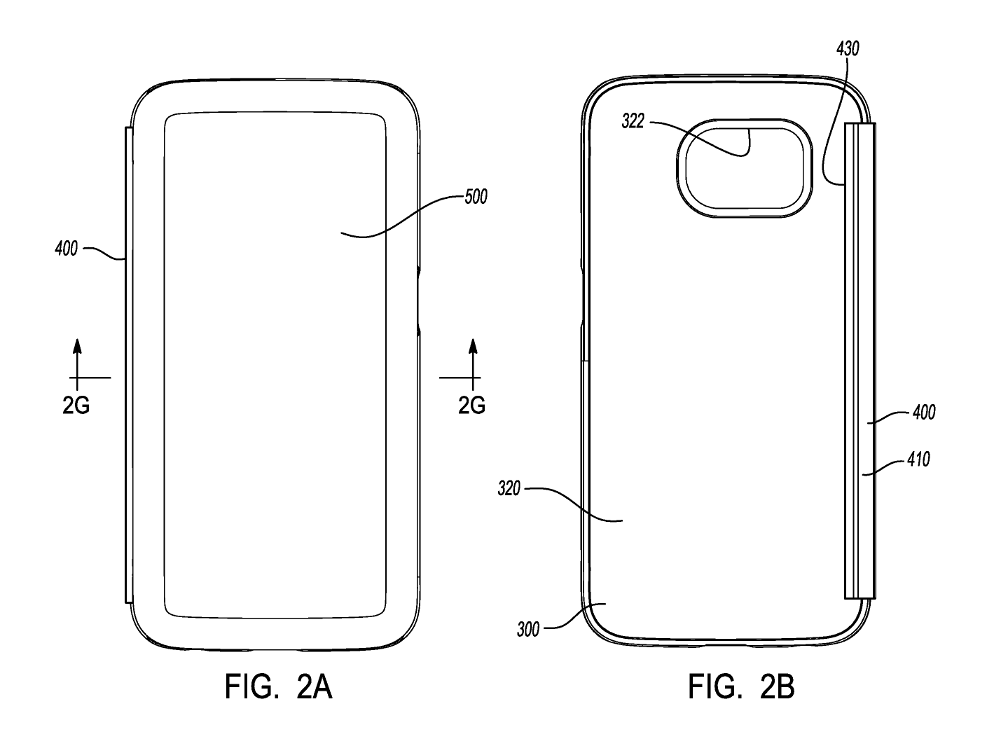

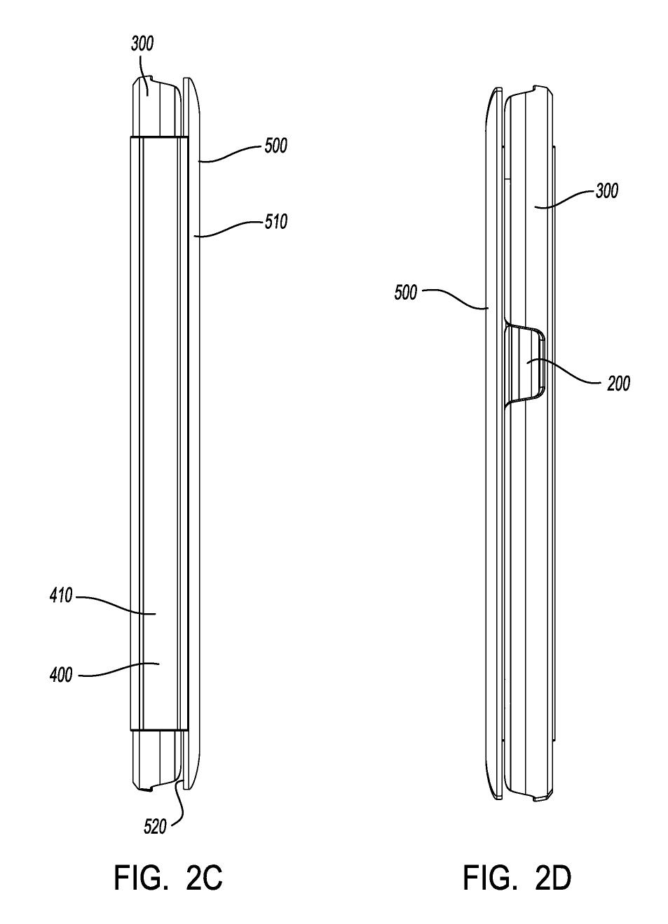

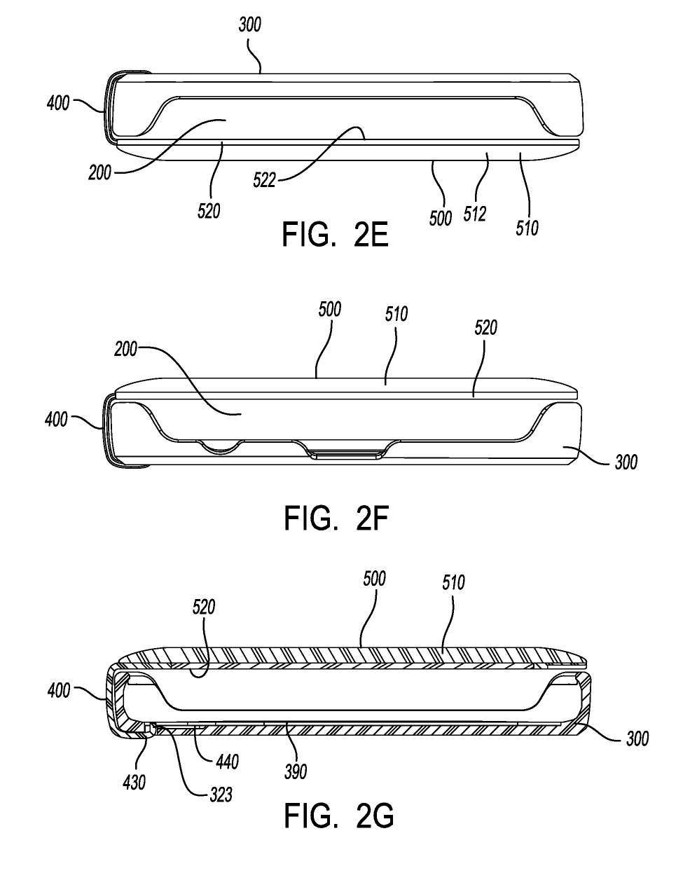

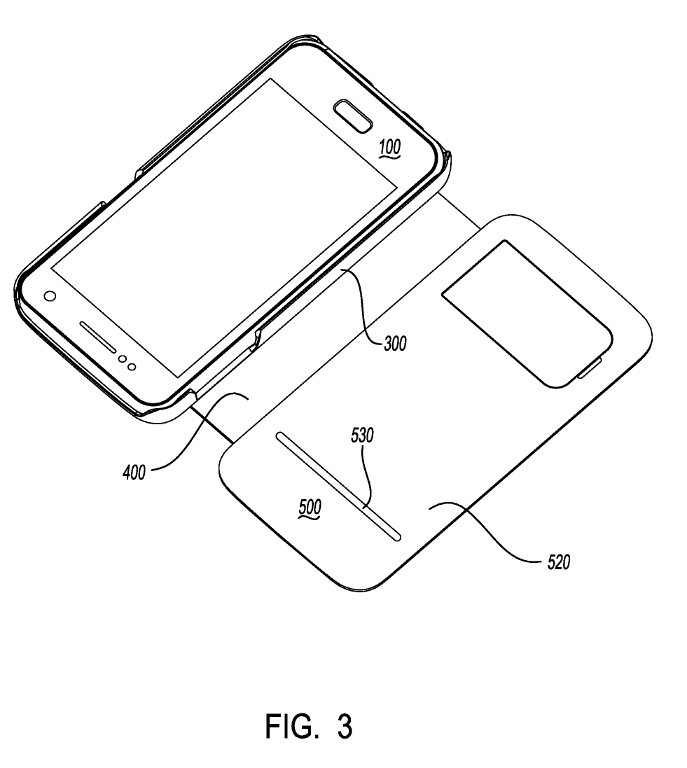

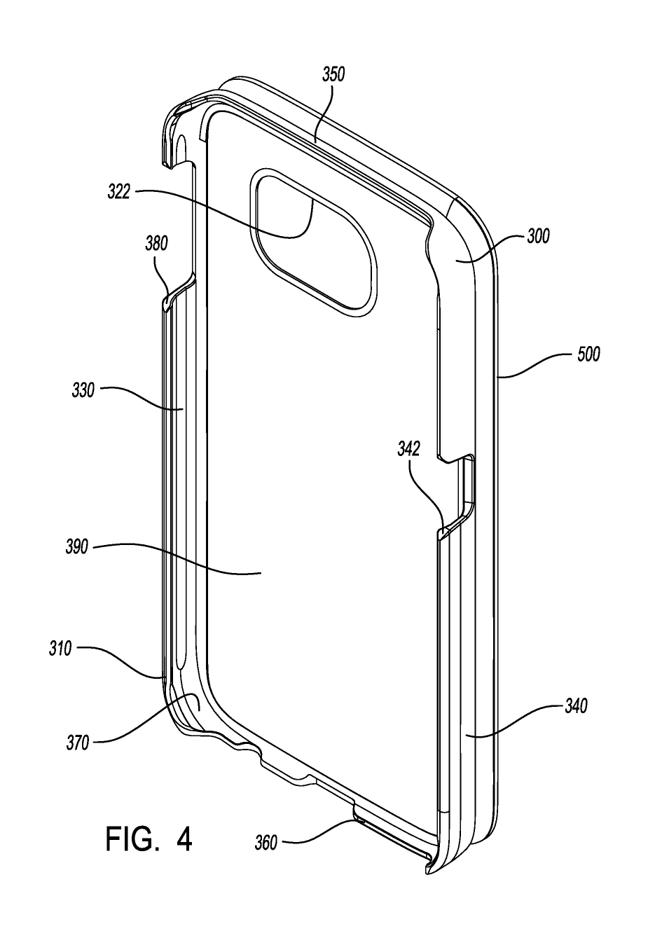

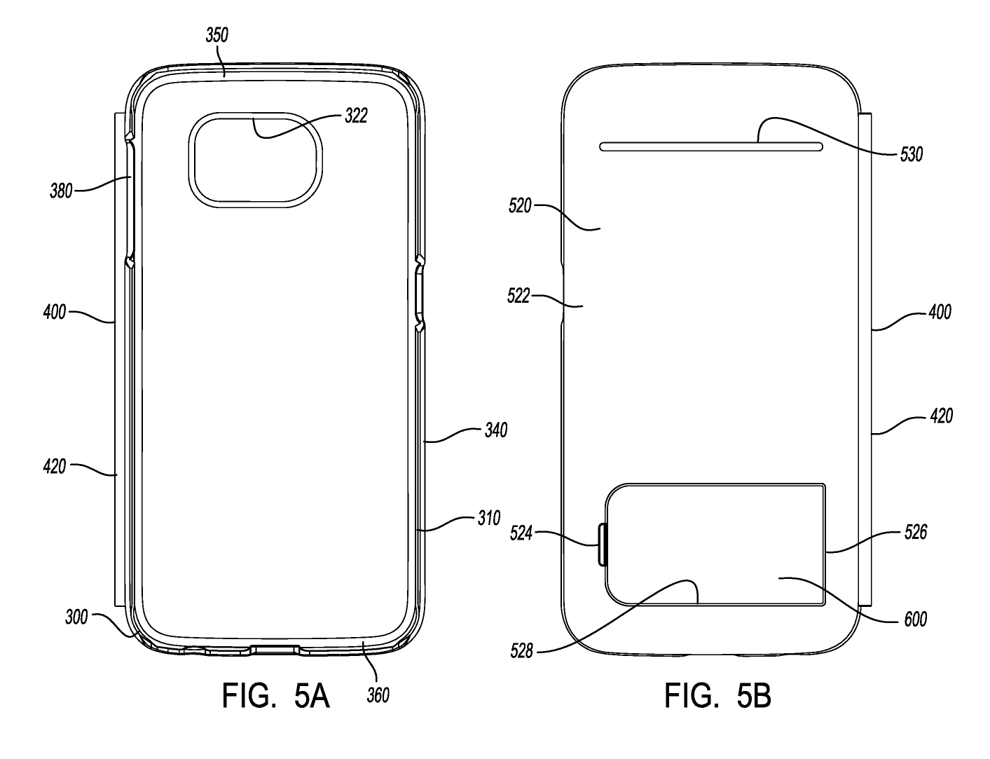

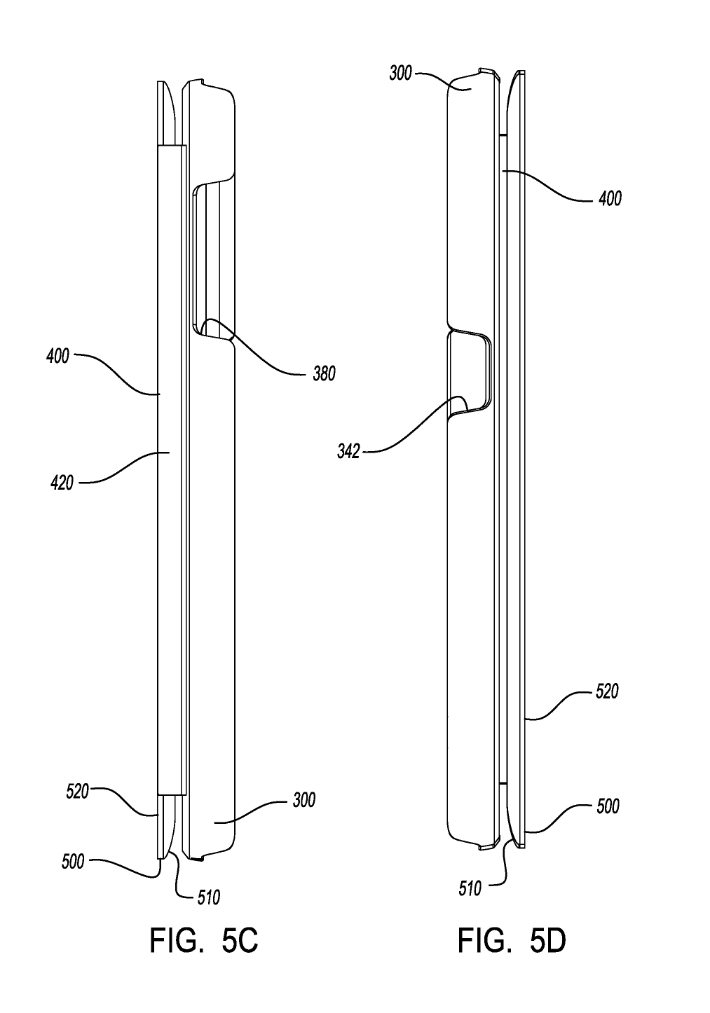

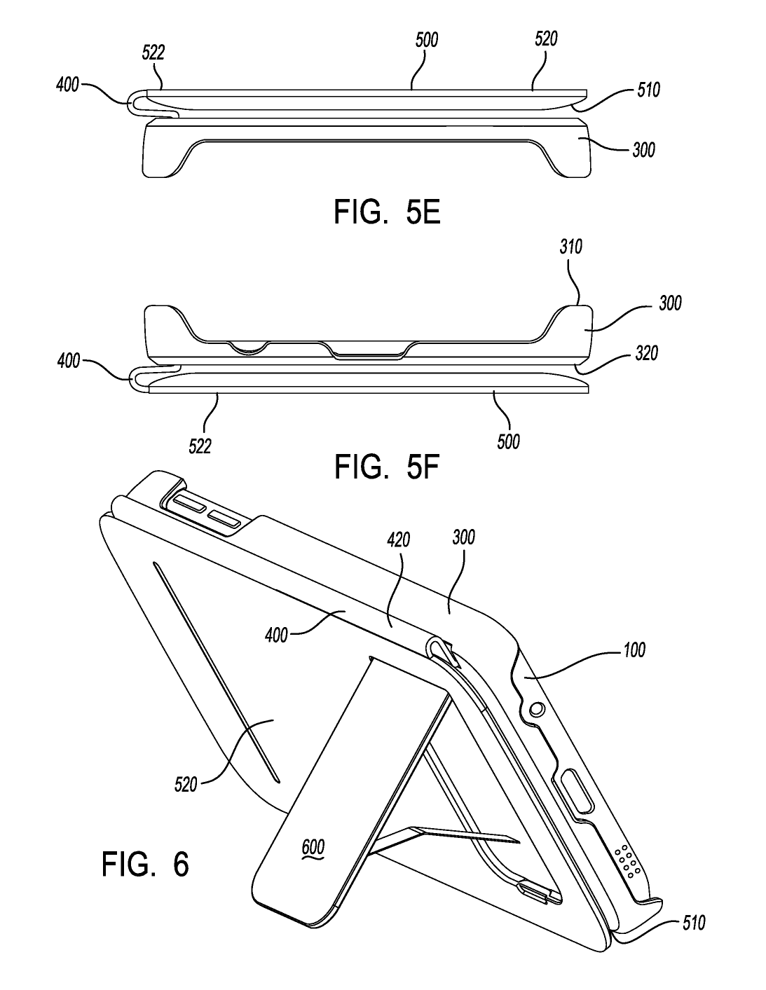

FIGS. 1 and 2A-2F depict different views of a protective case 200 for mobile device without the mobile device 100 received within the case 200 and the case 200 in a fully closed position. FIG. 2G is a more detailed cross-sectional view of the protective case 200 illustrated in FIG. 2A taken along cross-section line 2G-2G showing in greater detail the construction of the case and the relationship and configuration of the shell 300, panel 400 and cover 500 portions of the case 200. FIG. 3 illustrates the protective case 200 for mobile device in a first open position with the mobile device 100 received therein. FIGS. 4 and 5A-5F depict different views of the protective case 200 for mobile device in a second open position without the mobile device received within the case 200.

As disclosed in FIGS. 1-8, the protective case 200 includes a shell portion 300 having a back face wall 320 and left-side and right-side walls 330, 340 and top-side and bottom-side walls 350, 360. As well shown in FIGS. 4, 5, and 7, front plane 310 includes the ends of the left-side and/or right-side walls 330, 340 furthest away from the back face wall 320. In the FIGs., front plane 310 is labelled at the ends of left-side and/or right-side walls 330, 340. The side walls, 330, 340, 350 and 360 reside between the front plane 310 and back face wall 320. Each of the front plane 310 and walls 320, 330, 340, 350 and 360 are dimensioned to correspond in dimension to the front and back faces, and left, right, top and bottom sides of a mobile device 100, respectively.

Collectively the side walls 330, 340, 350 and 360 define a perimeter 370 between the front plane 310 and the back face wall 320 of the protective case 200 and are dimensioned to receive and retain the mobile device 100 within the case 200 as depicted in the drawings.

The shell portion 300 is defined by inner and outer surfaces, respectively, and dimensioned to cover the back face of the mobile device 100. The shell 300 may be configured to extend to the perimeter of the mobile device 100 at the back face boundary, which is the perimeter defined by the intersection of the side walls and the back face of the mobile device 100.

The shell portion 300 may be configured to cover the entire, a majority, half or less than half of the back face of the mobile device 100 and may be configured to extend to or around the entire, a majority, half or less than half of the perimeter of the mobile device 100 at the back face boundary,

In the illustrated implementation, the shell portion 300 is configured to cover the back face of the mobile device 100, with the exception of the flash and camera lens window aperture 322 a recess area 342 for facilitating the removal or insertion of the mobile device 100, and control apertures 380 to allow for access to, or user utilization of user controls, additional touchscreen interface, and/or other device features (e.g., speakers, cameras, lights, microphone, etc.) that are located on the side walls and/or back face of the mobile device 100. The shell 300 in the illustrated implementation is also dimensioned to extend about the entire perimeter of the back face of the mobile device 100. It should be understood however, that alternative configurations may be employed. Perimeter regions in the shell 300 that reside between one or more of the corners, for example may be removed and/or perimeter corner regions may be removed.

The shell portion 300 may have a liner layer 390 attached on the back face wall 320. The liner layer 390 is configured to be made of a softer material (e.g., a synthetic felt) than the shell portion 300 to further protect and/or cushion the mobile device.

The protective case 200 also comprises a front cover portion 500 which ma have an outer layer 510 and an inner layer 520 or panels. The cover portion 500 is generally dimensioned to cover the entire front face (e.g., the touchscreen) of the mobile device 100 when the case is in a closed position. It is, however, contemplated that the front cover portion 500 may cover less than the entire front face (e.g., a majority, half or less than half of the front face of the mobile device) and/or may be configured to extend around less than the entire perimeter of the front face of the mobile device (e.g., a majority, half or less than half of the perimeter of the mobile device 100).

The protective case 200 may include a hinged connection panel portion 400 extending between the cover 500 and the shell portion 300 and attach the cover 500 and the shell 300 to one another so that the two portions (500 and 300) can rotate relative to one another at a living joint or hinge region 430. As well shown in FIGS. 2 and 3, the panel portion 400 includes an outer panel surface 410 that faces out and an inner panel surface 420 that faces in when case 200 is in a closed position. The panel portion 400 may have an extension portion 440 that can be attached to the shell portion in any suitable way (e.g., mechanical and/or via adhesive). For example, an end section of the extension portion 440 may be inserted and adhered into a slot or cavity 323 on the back of the shell 300 or inserted between the back face wall 320 of the shell 300 and the liner layer 390 to secure the panel portion 400 to the shell portion 300. One of ordinary skill in the art, however, would understand that there are numerous alternative configurations that may be employed.

In the illustrated embodiment, the hinge panel portion 400 and the inner layer 520 of the cover portion 500 are formed as a single unit. It should be understood however, that alternative configurations may be employed.

The hinge panel portion 400 may be formed of flexible material so that the cover portion 500 can be moved or rotated from a closed position to an open position through the panel portion 400. Alternatively the hinge panel 400 may be formed of a mechanical hinge, like those used in a conventional door mount, but with one side connected to the shell portion 300 and the other side extending to form or being connected to the front cover 500.

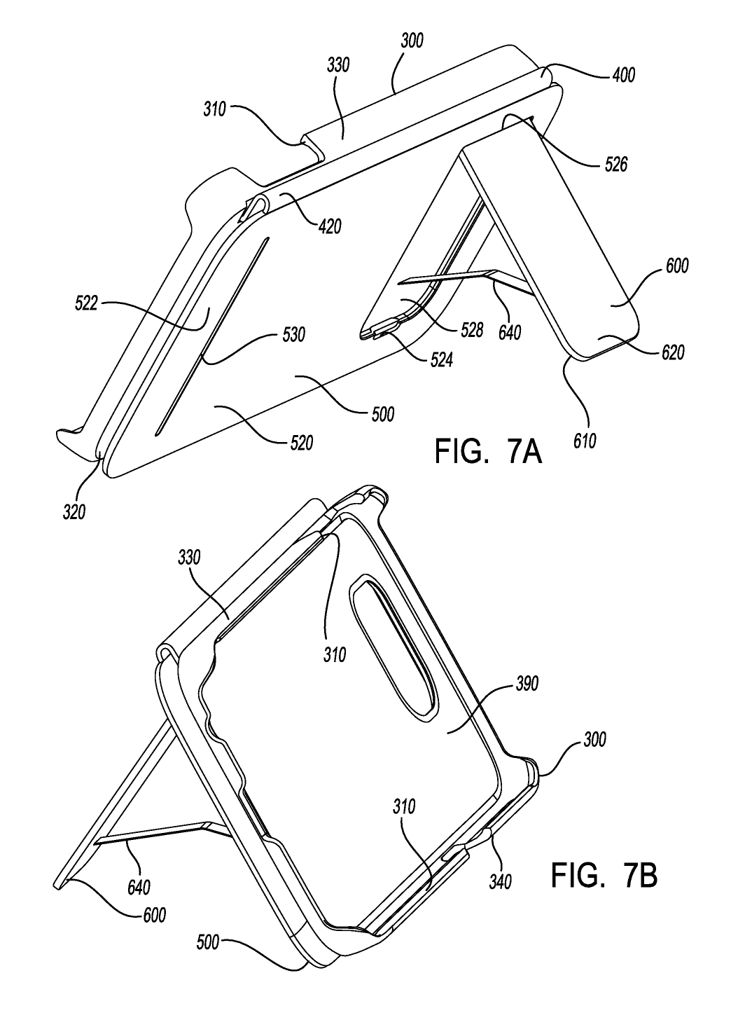

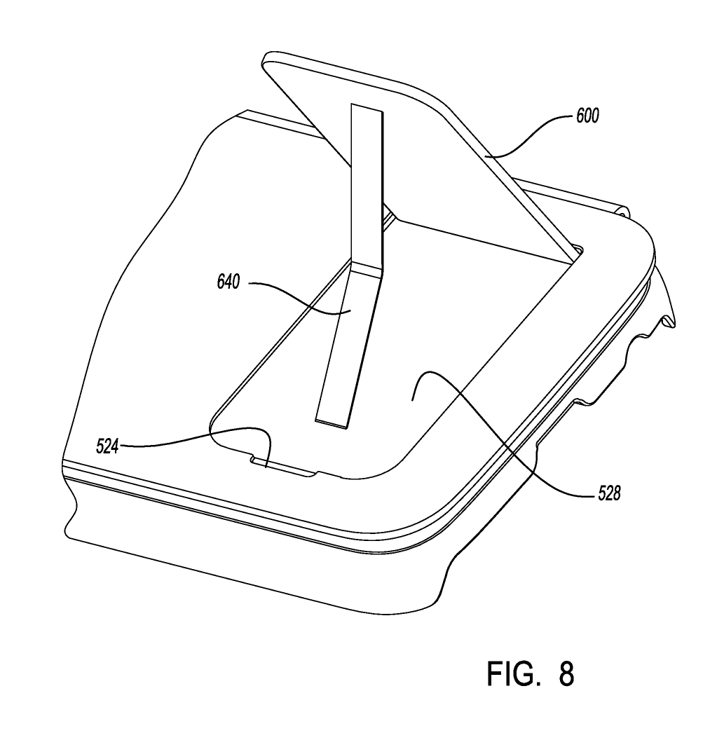

The inner layer 520 of the cover portion 500 includes an opening 528 sized to receive and retain in position an extendable stand 600 that is hinged to the inner surface 522 of the front cover 500. The extendable stand 600 is configured to open and close along hinge 526. As shown in FIG. 7A, the extendable stand 600 includes an inner stand layer 610 that faces toward inner layer 520 and an outer stand layer 620 that faces away from inner layer 520 when extendable stand 600 is open.

The inner layer 520 of the cover 500 may have a recessed region 524 to facilitate the user grasping the stand 600 when opening and/or closing the stand 600. One or more straps 640 may be used to limit and/or stabilize the rotation of the stand 600. A snap lock in the recessed area may also be included to secure or retain the stand 600 in a closed position.

FIG. 6 illustrates the protective case 200 in an operating position with the mobile device 100 received within the shell portion 300 and the extendable stand 600 hinged outward from the inner layer 520 of the cover 500 in an open position to support the cover and the mobile device on edge in the illustrated operating position. FIGS. 7A-7B are back face and front face perspective views, respectively, of the protective case 200 illustrated in FIG. 6 with the mobile device being removed from the case to further illustrate the configuration and construction of the case components.

Thus, the case 200 is provided with an extendable stand 600 that is hidden or concealed when the case 200 is in a closed position, yet when the case 200 is open, the stand 600 is revealed and can be extended to provide support.

While the shell 300 and front cover portions 500 together with panel 400 and the extendable stand 600 may be mechanically attached to form an integrated case 200 construction or construct, it should be understood that it is contemplated that portions of one or more of the layers may be co-molded, or each of the components may be separately formed and mechanically attached to one another by clips, snaps or latches between each of the components. A combination of co-molding and mechanical attachment of the layers or portions thereof may also be employed.

FIG. 8 best illustrates the retention strap 640 that may be provided to limit rotation and to stabilize the extendable stand 600 to maintain a fixed position.

The case 200 is properly dimensioned and has sufficient flexibility to al low the user to insert and remove the mobile device 100 for which the case is designed into and out of the shell portion 300 without damage thereto. The flexibility may be implemented via the construction materials employed and the configuration of the co-molded layers or components.

The materials that form the component elements may be selected based on their hardness or rigidity. For example, the shell portion 300 may be made of a first material that has a first hardness or rigidity, and the cover portion 500 may be made of a second material that has a second hardness or rigidity that is different from the first hardness, In a preferred implementation, the first hardness is greater than the second hardness. In another embodiment the first rigidity is greater than the second rigidity and in yet another embodiment the materials that form the shell portion and the front cover portion are the same and have the same rigidity and hardness.

In the present embodiment, the material that forms the panel 400 is the same as the material that forms the inner layer 520 of the cover portion 500,

In the present embodiment, the material that forms pivot stand 600 is the same as the material that forms the inner layer 520 of the cover portion 500.

The shell portion 300 may be formed of a composition comprised of one or more materials including but not limited to polycarbonate (PC); thermoplastic urethane (TPU), thermoplastic elastomer (TPE), acrylonitrile butadiene styrene (ABS), fiber, nylon, metal, silicone rubber, or any combination thereof.

The extendable stand 600, the panel 400 and the outer and inner layers 510, 520 of the cover portion 500 may be formed, for example, of a composition comprised of TPU and/or TPE, silicone rubber, leather, textile material or combination thereof or other suitable material.

Each of the foregoing and various aspects, together with those set forth in the claims and described in connection with the embodiments of the protective cases summarized above or otherwise disclosed herein including the drawings may be combined to form claims for a device, apparatus, system, method of manufacture, and/or use without limitation.

Although the various inventive aspects are herein disclosed in the context of certain preferred embodiments, implementations, and examples, it will be understood by those skilled in the art that the present invention extends beyond the specifically disclosed embodiments to other alternative embodiments and/or uses of the invention and obvious modifications and equivalents thereof. In addition, while a number of variations of the various aspects have been shown and described in detail, other modifications, which are within their scope will be readily apparent to those of skill in the art based upon this disclosure. It should be also understood that the scope this disclosure includes the various combinations or sub-combinations of the specific features and aspects of the embodiments disclosed herein, such that the various features, modes of implementation, and aspects of the disclosed subject matter may be combined with or substituted for one another. Thus, it is intended that the scope of the present invention herein disclosed should not be limited by the particular disclosed embodiments or implementations described above, but should be determined only by a fair reading of the claims.

Similarly, this method of disclosure, is not to be interpreted as reflecting an intention that any claim require more features than are expressly recited in that claim. Rather, as the following claims reflect, inventive aspects lie in a combination of fewer than all features of any single foregoing disclosed embodiment. Thus, the claims following the Detailed Description are hereby expressly incorporated into this Detailed Description, with each claim standing on its own as a separate embodiment.

What is claimed is:

1. A protective case for a mobile electronic device configured to be user removable from said mobile electronic device, wherein said mobile device includes a height that is defined as the distance between a front face and a back face of the mobile device, a perimeter defined by top, bottom, right, and left sides residing between the front and back faces, and corners defined at the intersecting regions of the sides, said protective case comprising:
a shell portion made of a first material that is dimensioned to cover at least a portion of the back face of the mobile device and retentively house the mobile device within a compartment formed within the shell portion, the shell portion including a slot;
a flexible panel portion made of a second material, an end section of the panel portion being inserted through the slot and secured to the shell portion;
a front cover portion having an inner layer and an outer layer, the front cover portion being mechanically and flexibly attached to the shell through the panel portion, the inner layer being an extension of the flexible panel portion and made of a second material, wherein the inner layer is configured to face and cover at least a portion of the front face of the mobile electronic device when the mobile device is retentively housed within the shell portion and the case is in a closed position;
a pivot stand made of the second material, the pivot stand being hingedly attached to the inner layer of the front cover portion and configured and dimensioned to rotate outwardly at a hinge to support the shell on edge and to support the mobile device housed in the case when the case is in an operating position, the pivot stand being further configured and dimensioned to remain concealed from view when the case is in a closed position;
an opening in the inner layer configured and dimensioned to receive and retain the pivot stand when the pivot stand is not rotated outwardly; and
one or more straps configured and dimensioned to limit and/or stabilize the rotation of the pivot stand.

2. A protective case for a mobile electronic device configured to be user removable from said mobile electronic device, wherein said mobile device includes a height that is defined as the distance between a front face and a back face of the mobile device, a perimeter defined by top, bottom, right, and left sides residing between the front and back faces, and corners defined at the intersecting regions of the sides, said protective case comprising:
a shell portion that is dimensioned to cover at least a portion of the back face of the mobile device and retentively house the mobile device within a compartment formed within the shell portion;
a flexible panel portion;
a front cover portion mechanically and flexibly attached to the shell through the panel portion, wherein the cover portion is configured to cover at least a portion of the front face of the mobile electronic device when mobile device is retentively housed within the shell portion and the case is in a closed position; and
a pivot stand that is hingedly attached to the front cover portion and configured to rotate outwardly at a hinge to support the shell on edge and to support the mobile device in an operating position when the mobile device is housed in the case.

3. The protective case of claim 2, wherein the front cover portion comprises an inner layer and an outer layer.

4. The protective case of claim 3, wherein the inner layer and the flexible panel portion are formed as a unitary element.

5. The protective case of claim 3, wherein the pivot stand is attached to the inner layer of the front cover portion.

6. The protective case of claim 3, further comprising an opening in the inner layer configured and dimensioned to receive and retain the pivot stand when the pivot stand is not rotated outwardly.

7. The protective case of claim 2, further comprising one or more straps configured and dimensioned to limit and/or stabilize the rotation of the pivot stand.

8. The protective case of claim 3, wherein the inner layer of the front cover portion is an extension of the flexible panel portion.

9. The protective case of claim 3, wherein the inner layer of the front cover portion is made of a second material.

10. The protective case of claim 9, wherein the shell portion is made of a first material, the first material being more rigid and more hard than the second material.

11. The protective case of claim 9, wherein the flexible e portion is made of the second material.

12. The protective case of claim 9, wherein the pivot stand is made of the second material .

13. The protective case of claim 2, wherein the shell portion is properly dimensioned and has sufficient flexibility to allow the user to insert and remove the mobile device into and out of the shell portion without damage to the shell portion.

14. The protective case of claim 2, wherein the pivot stand is concealed from view when the case is in a closed position.

15. The protective case of claim 2, wherein an end section of the panel portion is inserted through a slot or cavity in the shell portion and secured to the shell portion.

16. The protective case of claim 2, further comprising at least one control aperture through the shell portion to al low the user to access user controls, additional touchscreen interface, and/or other device features.

17. A protective case for a mobile electronic device comprising:
a shell portion configured and dimensioned to retentively house the mobile device within a compartment, the shell portion including a back face wall within the compartment and an outside wall opposite the back face wall;
a front cover portion having an inner layer and an outer layer, the front cover portion being mechanically attached to the shell through a flexible panel portion;
a pivot stand that is hingedly attached to the front cover portion and configured to rotate outwardly at a hinge; and
wherein the flexible panel portion is configured to flex and enable at least an operating position and a closed position, the case being configured in the operating position when the outer layer and the outside wall are oriented to face each other and are positioned in close proximity and the pivot stand is rotated outwardly from the front cover portion to support the case, the case being in the closed position when the inner layer and the back face wall are oriented to face each other and are positioned on opposite sides of the mobile device and the pivot stand is not rotated outwardly from the front cover.

18. The protective case of claim 17, wherein the inner layer and the flexible panel portion are formed as a unitary element.

19. The protective case of claim 18, wherein an end section of the panel portion is inserted through a slot or cavity in the shell portion and secured to the shell portion.

20. The protective case of claim 17, further comprising one or more straps configured and dimensioned to limit and/or stabilize the rotation of the pivot stand.
